(19) United States
(12) Patent Application Publication
(10) Pub. No.: US 2020/0031120 A1
(43) Pub. Date: Jan. 30, 2020

(54) FLUIDIC DIE WITH MASK REGISTER SETS

(71) Applicant: HEWLETT-PACKARD DEVELOPMENT COMPANY, L.P., Spring, TX (US)

(72) Inventors: Daryl E Anderson, Corvallis, OR (US); Eric T Martin, Corvallis, OR (US)

(73) Assignee: HEWLETT-PACKARD DEVELOPMENT COMPANY, L.P., Spring, TX (US)

(21) Appl. No.: 16/482,990

(22) PCT Filed: Apr. 14, 2017
(86) PCT No.: PCT/US2017/027649

§ 371 Date: Aug. 1, 2019

(51) Int. Cl. B41J 2/045; G06K 15/10; G11C 5/02

(52) U.S. Cl. CPC B41J 2/04543; B41J 2/04581; B41J 2/175; G06K 15/107; G11C 5/02; B41J 2/04541

(57) ABSTRACT

A fluidic die may include an array of fluid actuators, an actuation data register to store actuation data that indicates each fluid actuator to actuate for a set of actuation events, at least one storage device to store sets of mask data, each set of mask data indicating a set of fluid actuators of the array enabled for actuation for a respective actuation event of the set of actuation events, sequencing logic coupled to the at least one storage device to select one of the sets of mask data after each actuation event of the set of actuation events and actuation logic to electrically actuate a subset of the fluid actuators based at least in part on the actuation data register and the sequenced set of mask data for the respective actuation event.

### BACKGROUND

Fluidic dies may control movement and ejection of fluid. Such fluidic dies may include fluid actuators that may be actuated to thereby cause displacement of fluid. Some example fluidic dies may be printheads, where the fluid may correspond to ink.

### BRIEF DESCRIPTION OF THE DRAWINGS

FIG. 1 is a block diagram schematically illustrating some components of an example fluidic die.

FIG. 2 is a flow diagram of an example method for actuating a subset of fluid actuators on a fluidic die for an actuation event of a set of actuation events.

FIG. 3 is a block diagram schematically illustrates some components of an example fluidic die.

FIG. 4 is a block diagram schematically illustrating some components of an example fluidic die.

FIG. 5 is a block diagram schematically illustrating some components of an example fluidic die.

FIG. 6 is a block diagram schematically illustrating some components of an example fluidic die.

FIG. 7 is a block diagram schematically illustrating some components of an example fluidic die.

FIG. 8 is a block diagram schematically illustrating some components of an example fluidic die.

FIG. 9 is a block diagram schematically illustrating some components of an example fluidic die.

FIG. 10 is a block diagram schematically illustrating some components of an example fluidic die.

FIG. 11 is a block diagram schematically illustrating some components of one example of the fluidic die of FIG. 7 during an example set of actuation events.

FIG. 12 is a flow diagram of an example method for actuating subsets of fluid actuators during a set of actuation events.

FIG. 13 is a schematic diagram illustrating the actuation of fluid actuators of the fluidic die of FIG. 11 during the set of actuation events.

FIG. 14 is a block diagram schematically illustrating some components of an example fluidic die.

FIG. 15 is a block diagram schematically illustrating some components of an example mask register bit of the example fluidic die of FIG. 14.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION OF EXAMPLES

Examples of fluidic dies may comprise fluid actuators. The fluid actuators may include a piezoelectric membrane based actuator, a thermal resistor based actuator, an electrostatic membrane actuator, a mechanical/impact driven membrane actuator, a magneto-strictive drive actuator, or other such elements that may cause displacement of fluid responsive to electrical actuation. Fluidic dies described herein may comprise a plurality of fluid actuators, which may be referred to as an array of fluid actuators. Moreover, an actuation event, as used herein, may refer to concurrent actuation of fluid actuators of the fluidic die to thereby cause fluid displacement.

In example fluidic dies, the array of fluid actuators may be arranged in respective sets of fluid actuators, where each such set of fluid actuators may be referred to as a “primitive” or a “firing primitive.” A primitive generally comprises a group of fluid actuators that each have a unique actuation address. In some examples, electrical and fluidic constraints of a fluidic die may limit which fluid actuators of each primitive may be actuated concurrently for a given actuation event. Therefore, primitives facilitate addressing and subsequent actuation of fluid ejector subsets that may be concurrently actuated for a given actuation event. A number of fluid ejectors corresponding to a respective primitive may be referred to as a size of the primitive.

To illustrate by way of example, if a fluidic die comprises four primitives, where each respective primitive comprises eight respective fluid actuators (each eight fluid actuator group having an address 0 to 7), and electrical and fluidic constraints limit actuation to one fluid actuator per primitive, a total of four fluid actuators (one from each primitive) may be concurrently actuated for a given actuation event. For example, for a first actuation event, the respective fluid actuator of each primitive having an address of 0 may be actuated. For a second actuation event, the respective fluid actuator of each primitive having an address of 1 may be actuated. As will be appreciated, the example is provided merely for illustration purposes. Fluidic dies contemplated herein may comprise more or less fluid actuators per primitive and more or less primitives per die.

In examples described herein, a fluidic die may comprise an array of fluid actuators which is formed from multiple primitives. The fluidic die may further comprise an actuation data register and at least one storage device to store multiple sets of mask data. The actuation data register may store actuation data that indicates each fluid actuator to actuate for a set of actuation events.

Each set of mask data may indicate a set of fluid actuators of the array enabled for actuation for a respective actuation event of the set of actuation events. The fluidic die may comprise sequencing logic coupled to the at least one storage device to select one of the sets of mask data after each actuation event of the set of actuation events and actuation logic to electrically actuate a subset of the fluid actuators based at least in part on the actuation data register and the sequenced set of mask data for the respective actuation event. In examples disclosed herein, the sets of mask data may be selected and sequenced such that each fluid actuator of the array is enabled for actuation at some time during sequencing through a number of sets of mask data equal to the number of fluid actuators in each primitive or the number of primitives in the array. The order of sequencing between the different sets of mask data may vary.

In some of the examples described herein, a single “active” mask register is repeatedly loaded with the different sets of mask data from the at least one data storage device during the set of actuation events. Each set of mask data has a number of data elements or bits corresponding to the total number of fluid actuators in the array. The sequencing logic 340 loads a selected set of mask data from the at least one storage device into the active mask register for each actuation event of the set of actuation events. The sets of mask data loaded into the active mask register, one-by-one, for the actuation events are selected by the sequencing logic such that each fluid actuator of the array is enabled for actuation at some time during sequencing through a number of sets of mask data equal to the number of fluid actuators in each primitive or the number of primitives in the array.

In some of the examples described herein, the fluidic die may include multiple mask registers that alternate between an active state and an inactive state. When in an active state, the mask register of the multiple mask registers is “active” in that stored set of mask data is used by actuation logic to enable a subset of fluid actuators of the array. When in an inactive state, the mask register of the multiple mask registers is waiting to be loaded with a set of mask data, being loaded with mask data or having been loaded with mask data and awaiting being placed in an active state. During an actuation event of a set of actuation events, one of the mask registers may be in an active state while the other of the mask registers is in a loading state. In some implementations, the first and second sets of mask data may have the same pattern of mask data, but wherein the pattern of the mask data in the first mask register is shifted relative to the pattern of the mask data in the second mask register.

In such an implementation, the sequencer logic may switch the first and second mask registers between the loading state and the active state for the different actuation events of the set of actuation events. For example, during a first actuation event of a set, the first mask register may be active while the second mask register being loaded. During the next second actuation event the set, the now loaded second mask register may be active while the first mask register is being loaded with a new set of mask data. The alternating of the mask registers between an active state and a loading state may continue for each actuation event of the full set of actuation events until fluid actuator of the array has been enabled for actuation at some time during sequencing through a number of sets of mask data equal to the number of fluid actuators in each primitive or the number of primitives in the array.

In some implementations, the multiple mask registers may comprise more than two registers, wherein during each actuation event, one mask register is in the “active” state while the other mask registers are inactive, waiting to be loaded with a set of mask data, being loaded with mask data or having been loaded with mask data and awaiting being placed in an active state. By concurrently loading set of mask data into in active match registers while another active mask register is being used by actuation logic, the time to switch between different sets of mask data for different actuation of may be reduced.

In some of the examples described herein, the at least one storage device comprises a set of mask registers with each mask register storing a set of mask data. The set of mask registers store different sets of mask data such that sequencing through each of mask registers of the set results in each fluid actuator of the array being enabled for actuation at some time during sequencing through set of mask registers. In some of the described examples, each mask register of the set comprises a single pattern of mask data, wherein the single pattern of each mask register of the set is shifted relative to the single pattern of the mask data set stored in other mask registers of the set. In one implementation, sequencing logic selectively connects a selected one of the mask registers of the set and it stored set of mask data to actuation logic for each actuation event of a set of actuation events.

The single pattern of mask data in the sets of mask data and stored in the set of mask registers may identify a primitive of a first size. Different sets of mask data contained in different sets of mask registers may be selected. Therefore, it may be appreciated that examples contemplated herein may facilitate variable primitive size. For example, for a first set of actuation events, a first set of mask registers storing first sets of mask data may be selected and sequenced, forming first primitives of a first size as defined by the first sets of mask data in the first set of mask registers. For a second set of actuation events, a second set of mask registers storing second sets of mask data may be selected and sequenced, forming second primitives of a second size, different than the first size of the first primitives, as defined by the second sets of mask data in the second set of mask registers.

In one implementation, the entire set of mask registers is loaded with the sets of mask data during period of time during which the array of fluid actuators is not being actuated. In another implementation, some mask registers of the set may be loaded with their respective sets of mask data while another mask register and its set of mask data are active and being used by actuation logic to identify the subset of fluid actuators to be enabled during an actuation event. In some implementations, multiple sets of mask registers may be provided on a fluidic die in loaded with different sets of mask data corresponding to different primitive sizes for different sets of actuation events.

In some examples, a fluid actuator may be disposed in a nozzle, where the nozzle may comprise a fluid chamber and a nozzle orifice in addition to the fluid actuator. The fluid actuator may be actuated such that displacement of fluid in the fluid chamber may cause ejection of a fluid drop via the nozzle orifice. Accordingly, a fluid actuator disposed in a nozzle may be referred to as a fluid ejector.

Some example fluidic dies comprise microfluidic channels. Microfluidic channels may be formed by performing etching, microfabrication (e.g., photolithography), micromachining processes, or any combination thereof in a substrate of the fluidic die. Some example substrates may include silicon based substrates, glass based substrates, gallium arsenide based substrates, and/or other such suitable types of substrates for microfabricated devices and structures. Accordingly, microfluidic channels, chambers, orifices, and/or other such features may be defined by surfaces fabricated in the substrate of a fluidic die. Furthermore, as used herein a microfluidic channel may correspond to a channel of sufficiently small size (e.g., of nanometer sized scale, micrometer sized scale, millimeter sized scale, etc.) to facilitate conveyance of small volumes of fluid (e.g., picoliter scale, nanoliter scale, microliter scale, milliliter scale, etc.). Example fluidic dies described herein may comprise microfluidic channels in which fluidic actuators may be disposed. In such implementations, actuation of a fluid actuator disposed in a microfluidic channel may generate fluid displacement in the microfluidic channel. Accordingly, a fluid actuator disposed in a microfluidic channel may be referred to as a fluid pump.

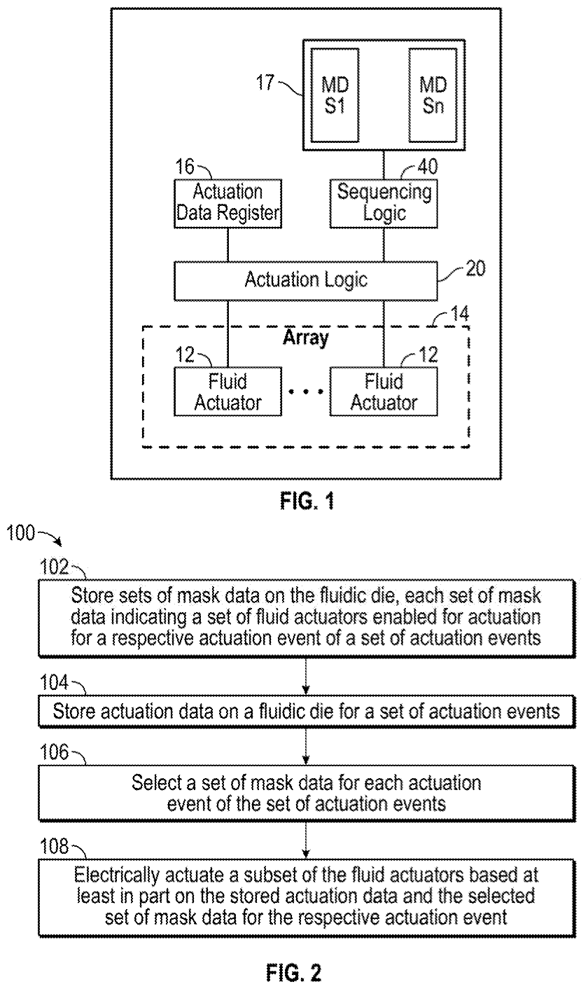

FIG. 1 is a block diagram schematically illustrating some components or portions of an example fluidic die 10 that stores sets of mask data, while sequencing through selected sets of the mask data. In one implementation, the sets of mask data may be selected and sequenced such that each fluid actuator of an array is enabled for actuation at some time during sequencing through a number of sets of mask data equal to the number of fluid actuators in each primitive or the number of primitives in the array. The order of sequencing between the different sets of mask data may vary.

Fluidic die 10 comprises fluid actuators 12, actuation data register 16, storage device 17, actuation logic 20 and sequencing logic 40. In one implementation, each of fluid actuators 12, actuation data register 16, storage device 17, actuation logic 20 sequencing logic 40 are located on or within a substrate.

Fluid actuators 12 comprise devices or elements that cause displacement of a fluid in response to electrical actuation. The fluid actuators 12 may include a piezoelectric membrane based actuator, a thermal resistor based actuator, an electrostatic membrane actuator, a mechanical/impact driven membrane actuator, a magneto-strictive drive actuator, or other such elements. In one implementation, fluid actuators 12 are in the form of fluid pumps. In another implementation, fluid actuators 12 are in the form of fluid ejectors which may be part of nozzles. In some implementations, fluid actuators 12 comprise a mixture of different types of fluid actuators the form of both pumps and ejectors.

In the example illustrated, fluid actuators 12 are in an array 14. In one implementation, array 14 comprise a row or column of such fluid actuators. In another implementation, array 14 may comprise fluid actuators 12 having other layouts or arrangements. As shown in FIG. 1, the array of fluid actuators 14 may comprise various numbers of fluid actuators 12.

Actuation data register 16 comprises a memory data register that may store actuation data that indicates each fluid actuator to actuate for a set of actuation events. Storage device 17 comprises storage elements that store sets of mask data. Each set of mask data has a mask data element corresponding to one of fluid actuators 12. In the example, storage device 17 stores mask data (MD) sets S1-Sn, wherein all of the sets or a portion of the sets of mask data may be sequenced during a set of actuation events such that each fluid actuator of an array is enabled for actuation at some time during the set of actuation events. In one implementation, the set of actuation events is equal to the number of fluid actuators in each primitive or the number of primitives in the array.

In one implementation, storage device 17 comprises sets of mask data that identify many different primitive sizes available for selection or use during different sets of actuation events. For example, storage device 17 may store four associated sets of mask data for designating a primitive size of four fluid actuators, may store five associated sets of mask data for designating a primitive size of five fluid actuators and so on. In such an implementation, the individual sets of mask data are selected and sequenced based upon the selected primitive size. In such an implementation, storage device 17 may comprise various types of memory elements or memory storage devices.

In one implementation, storage device 17 may comprise at least one set of mask registers, wherein each mask register stores a set of mask data. Each mask register may have bit or data storage location corresponding to one of fluid actuators 12. In one example, the number of data registers in a set may correspond to the number of actuation events in a set of actuation events. The selection and sequencing through the set of mask data in each of the data registers of an individual set of data registers may result in each fluid actuator being enabled at some time during the set of actuation events.

In one implementation, different sets of mask registers may correspond to different primitive sizes. For example, a first set of mask data registers may correspond to a first primitive size and a second set of mask data registers may correspond to a second primitive size different than the first primitive size.

Actuation logic 20 comprises logic circuitry such as processing hardware and/or software, coupled to actuation data register 16, mask register 18 and fluid actuators 12. Actuation logic 20 is to electrically actuate a subset of fluid actuators 12 based at least in part upon the selected set of mask data for an individual actuation event of a set or larger series of actuation events.

Sequencing logic 40 comprises logic circuitry that selects and sequences different sets of mask data for individual actuation events of a set or series of actuation events. After each actuation event, 16 logic 40 selects another set of mask data for the next actuation event of the set. As described above, in one implementation, the sets of mask data are selected and sequenced by sequencing logic 40 such that each fluid actuator of each primitive or each fluid actuator of the array is enabled at some time during the set of actuation events.

In fluidic die 10 and each of the fluidic dies described herein, an actuation data register, a mask register and actuation logic are illustrated and described with respect to a single array of fluid actuators. It should be appreciated that each of such fluidic dies may comprise multiple arrays of fluid actuators. In such implementations, each array of fluid actuators may have an associated actuation data register, mask register and actuation logic. In some implementations, each array of fluid actuators may have dedicated mask data generation circuitry.

FIG. 2 is a flow diagram of an example method 100 for controlling the electrical actuation of fluid actuators on a fluidic die. For purposes of discussion, method 100 is described as being carried out with fluidic die 10. It should be appreciated that method 100 may be carried out with any of the fluidic dies described hereafter or other similar fluidic dies.

As indicated by block 102, sets of mask data are stored on fluidic die 10. Each set of mask data indicates a set of fluid actuators of an array of fluid actuators enabled for actuation for respective actuation event of a set of actuation events. The storing of such sets of mask data may take place during periods in which die 10 is not in use.

As indicated by block 104, actuation data is stored on fluidic die 10. For example, the actuation data may be stored in actuation data register 16. Actuation data indicates each fluid actuator 12 of array 14 to actuate for a set of actuation events. It should be appreciated that blocks 102 and 104 may be implemented in any order.

As indicated by block 106, a set of mask data from the stored sets, is selected after each actuation event of the set of actuation events. As indicated by block 108, a subset of fluid actuators is electrically actuated based at least in part on the stored actuation data and the selected set of mask data for the respective actuation event. In one implementation, the sets of mask data are selected and sequenced during the actuation events of the set of actuation events such that each fluid actuator 12 of an array 14 is enabled for actuation at some time during the set of actuation events. In one implementation, the set of actuation events is equal to the number of fluid actuators in each primitive or the number of primitives in the array.

In many circumstances, the same sets of mask data are utilized during multiple sets of actuation events and multiple sets of actuation data in actuation data register 16. Once the sets of mask data has been stored, printing or fluid ejection is initiated by loading and firing one column or array of fire or actuation data after another (each column has as many fire pulses as nozzles per primitive—or addresses). Each time the header “info” bits associated with the actuation data may be set to say “use the same sets of mask data that are already loaded”. In this manner, the fluid ejection or printing may go on unabated (without waiting to load new sets of mask data into mask registers.

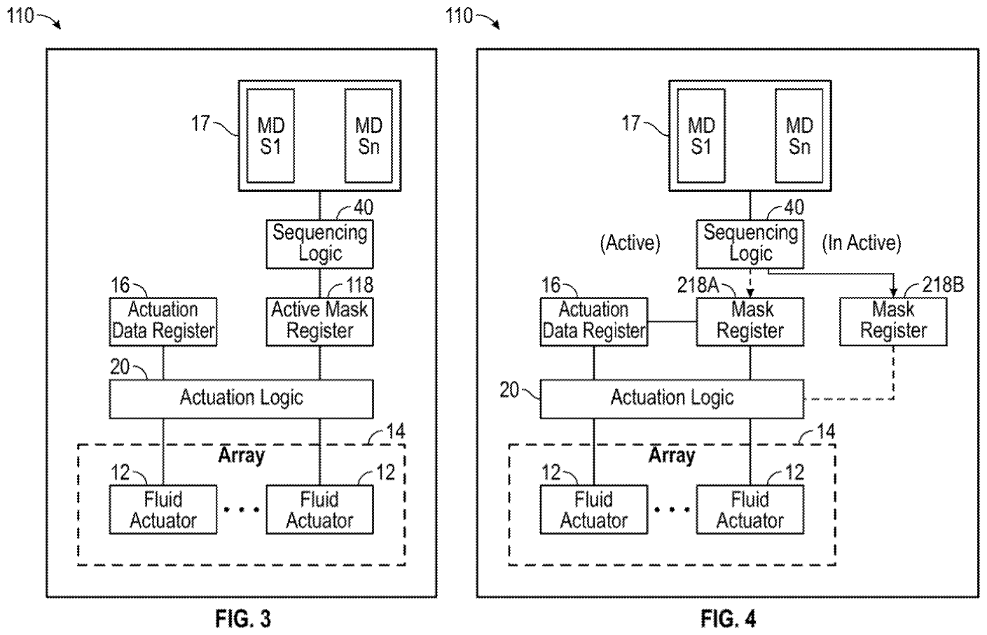

FIG. 3 is a block diagram schematically illustrating some components of an example fluidic guide 110. Fluidic die 110 is similar to fluidic die 10 described above except that fluidic die 110 additionally comprises active mask register 118. Those remaining components of fluidic die 110 which correspond to components of fluidic die 10 are numbered similarly.

Active mask register 118 comprises a memory data register that stores the set of mask data selected by sequencing logic 40 from the at least one memory storage device 17. The single “active” mask register 118 is repeatedly loaded with the different sets of mask data from the at least one data storage device during the set of actuation events. Each set of mask data has a number of data elements or bits corresponding to the total number of fluid actuators in the array. Active mask register 118 is connected to actuation logic 20 such that actuation logic 20 actuates is a subset of fluid actuators 12 of array 14 four and actuation event based at least in part upon the set of mask data presently populating register 118. Prior to each actuation event of the set of actuation events, sequencing logic 40 selects one set of mask data from the at least one storage device 17 and loads the selected set of mask data into register 118 for use by actuation logic 20 during the next subsequent actuation event of the set of actuation events. As discussed above, sequencing logic 40 selects the sets of mask data such that that each fluid actuator of each primitive or each fluid actuator of the array is enabled at some time during the set of actuation events, wherein the set of actuation events comprises a number of actuation events corresponding to the number of fluid actuators in each primitive.

FIG. 4 is a block diagram schematically illustrating some components of an example fluidic guide 210. Fluidic die 210 is similar to fluidic die 10 described above except that fluidic die 210 additionally comprises mask registers 218A and 218B (collectively referred to as mask registers 218). Those remaining components of fluidic die 210 which correspond to components of fluidic die 10 are numbered similarly.

Each of mask register 218 comprises a memory data register that stores the set of mask data selected by sequencing logic 40 from the at least one memory storage device 17. Each of mask register 218 alternates between an active state and an inactive state. When in an active state, the mask register is “active” in that it's stored set of mask data is used by actuation logic 20 to enable a subset of fluid actuators 512 of the array 514. When in an inactive state, the mask register is waiting to be loaded with a set of mask data, being loaded with mask data or having been loaded with mask data and awaiting being placed in an active state. During an actuation event of a set of actuation events, one of the mask registers 218 may be in an active state while the other of the mask registers 218 is in a loading state. In some implementations, the first and second sets of mask data may have the same pattern of mask data, but wherein the pattern of the mask data in the first mask register is shifted relative to the pattern of the mask data in the second mask register.

Sequencer logic 40 mask registers 218A and 218B between the loading state and the active state for the different actuation events of the set of actuation events. For example, during a first actuation event of a set, the first mask register 218A may be active (as indicated by the solid line connecting mask registers 218A two actuation logic 20) while the second mask register 218B is being loaded by sequencing logic 40 with a selected set of mask data for the next actuation event of the set (as indicated by the solid arrow connecting logic 42 mask register 218B). During the next second actuation event the set, the now loaded second mask register 218B may be active while the first mask register 218A is being loaded with a new set of mask data for the next or third actuation event of the set. The alternating of the mask registers 218 between an active state and a loading state may continue for each actuation event of the full set of actuation events until each fluid actuator 12 of the array 14 has been enabled for actuation at some time during sequencing through a number of sets of mask data equal to the number of fluid actuators in each primitive or the number of primitives in the array. As discussed above, sequencing logic 40 selects the sets of mask data such that that each fluid actuator 12 of each primitive or each fluid actuator 12 of the array 14 is enabled at some time during the set of actuation events, wherein the set of actuation events comprises a number of actuation events corresponding to the number of fluid actuators 12 in the primitive with the selected primitive size.

In some implementations, the multiple mask registers 218 may comprise more than two registers, wherein during each actuation event, one mask register 218 is in the “active” state while the other mask registers 218 are inactive, waiting to be loaded with a set of mask data, being loaded with mask data or having been loaded with mask data and awaiting being placed in an active state. By concurrently loading a set of mask data into inactive mask registers while another active mask register is being used by actuation logic 20, the time to switch between different sets of mask data for different actuation events of the set may be reduced.

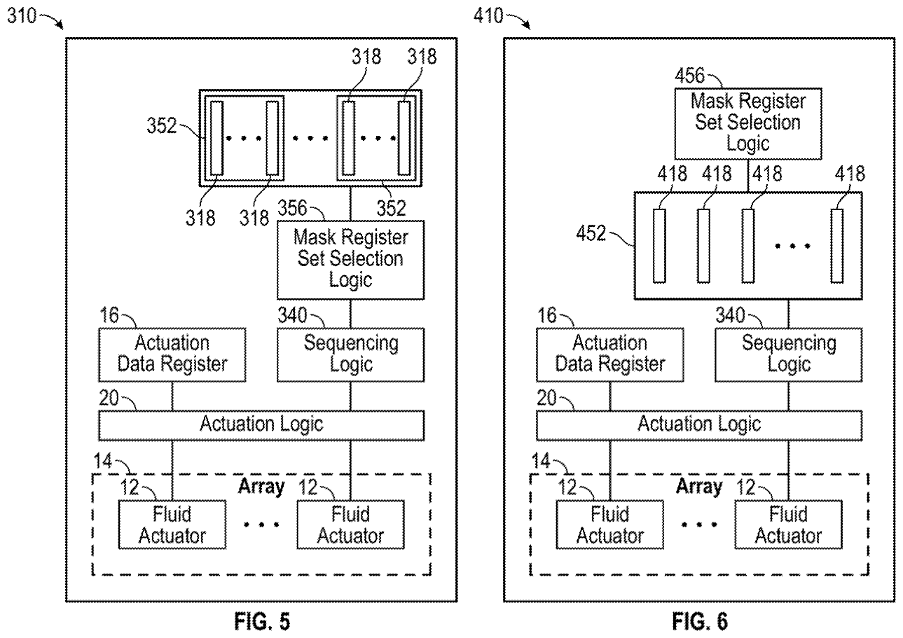

FIG. 5 is a block diagram schematically illustrates some components of an example fluidic die. Fluidic die 310 is similar to fluidic die 10 except that fluidic die 310 is specifically illustrated as comprising multiple sets 352 of mask registers 318 and is further comprising mask register set selection logic 356 and sequencing logic 340. Those remaining components of die 310 which correspond to points of die 10 are numbered similarly.

Each of mask register 318 comprises a memory data register storing a set of mask data having a storage element or bit corresponding to each fluid actuator 12 of array 14. Each set 352 of mask registers has a number of mask registers 318 corresponding to the number of fluid actuators in the primitive identified by the sets of mask data. Each set 352 of mask registers stores sets of mask data for being selected and sequenced during a set of actuation events. In one implementation, each set 352 of mask registers stores a collection of mask data sets that enable each fluid actuator of each primitive and of the array 14 during the set of actuation events.

The different sets 352 identify different patterns of mask data and/or different primitive sizes having different numbers of fluid actuators. For example, in one implementation, die 310 may comprise a first set 352 of mask registers having a pattern of 1 0 0 0 0, a second set 352 of the same size but having a different pattern of 1 1 0 0 0 and a third set 352 of the same size but having another different pattern of 1 1 1 0 0. In one implementation, die 310 may comprise a first set 352 of mask registers that store first sets of mask data for a first primitive size, a second set 352 of mask registers that store second sets of mask data for a second primitive size, different than the first primitive size and a third set 352 of mask registers that store sets of mask data for a third primitive size, different than the first primitive size and different than the second primitive size, for being selected and sequenced during a third set of actuation events.

Mask register set selection logic 356 selectively connects one of the sets 352 of mask registry 18 to sequencing logic 340. Mask registers set selection logic 356 may select the set 352 of mask registers 318 based upon an input or command received by die 310.

Sequencing logic 340 selects and connects an individual mask register 318 of the selected set 352 to actuation logic 20 for each actuation event of a set of actuation events. As a result, sequencing logic 340 connects a selected set of mask data of a larger collection of mask data sets to their respective actuation event of the set of actuation events.

FIG. 6 is a block diagram schematically illustrating some components of another example fluidic die 410. Fluidic die 410 is similar to fluidic die 10 except that fluidic die 410 is specifically illustrated as comprising mask registers 418, mask register loading logic 456 and sequencing logic 340. Those remaining components of fluidic die 410 which correspond to components of fluidic die 10 are numbered similarly.

Mask registers 418 comprise a set of memory data registers which are selectively connectable to actuation logic 20 by sequencing logic 340. Mask registers 418 store sets of mask data for a set of actuation events. The number of mask registers 418 may be equal to the largest number of actuation events in a set of actuation events and may be equal to the largest number of fluid actuators that may be identified for a primitive. Mask registers 418 may be loaded by mask register loading logic 456 each time that a new collection of mask data sets identifying a differently sized primitive is to be used.

Mask register loading logic 456 comprises circuitry, logic components and other hardware that loads mask registers 418 with sets of mask data. In one implementation, mask register loading logic 456 loads mask registers 418 with sets of mask data having the same pattern of mask data, but wherein the pattern in each of the mask registers 418 is shifted relative to the pattern in other mask registers 418. Mask register loading logic 456 loads a number of the mask registers 418 corresponding to the number of actuation events in a set of actuation events which corresponds to the number of fluid actuators in the selected primitive size. For example, with a selected primitive size of four fluid actuators, mask register loading logic 456 would load four of the mask registers 418. With a selected primitive size of six fluid actuators, mask register loading logic 456 would load six of the mask registers 418. With a selected primitive size of eight fluid actuators, mask register loading logic 456 would load eight of the mask registers 418. Depending upon the number of available mask registers 418 for being loaded with mask data and the selected primitive size for a set of actuation events, not all of mask registers 418 may be utilized during a set of actuation events. Such loading of mask registers 418 may take place at any time between sets of actuation events. In one implementation, mask register loading logic 456 loads mask registers 418 during periods of inactivity, such as between ejection tasks or print jobs.

As with sequencing logic 340 on die 310, sequencing logic 340 on die 410 selects and connects an individual mask register 418 to actuation logic 20 for each actuation event of a set of actuation events. Sequencing logic 340 sequences through a number of the mask registers corresponding to the number of actuation events and the number of fluid actuators in each primitive.

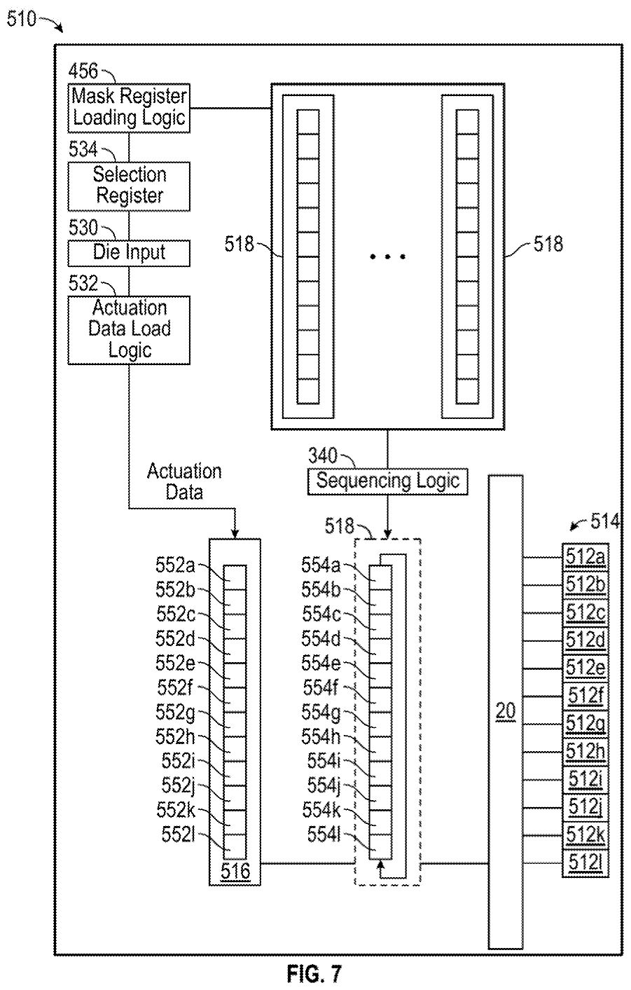

FIG. 7 is a block diagram schematically illustrating some components of an example fluidic die 510. As with fluidic die 410, fluidic die 510 loads sets of mask data which are selected and sequenced during actuation events of a set of actuation events to enable a subset of fluid actuators during each actuation event of the set of actuation events. Fluidic die 510 comprises fluid actuators 512a-i (collectively referred to as fluid actuator 512), actuation data register 516, mask registers 518, die input 530, actuation data load load logic 532, selection register 534, mask register loading logic 456, sequencing logic 340 and actuation logic 20.

Each of fluid actuator 512 is similar to fluid actuators 12 described above. In the example illustrated, die 510 is illustrated as comprising 12 fluid actuators 512a-512l forming an array 514. It should be appreciated that array 514 may have more or less of such fluid actuators 512.

Actuation data register 516 is similar to actuation data register 16 described above except that actuation data register 516 is specifically illustrated as comprises a set of bits 552a-l to store actuation data, where each respective bit 552a-l of the actuation data register 516 corresponds to a respective fluid actuator 512a-l. As shown, actuation data load logic 532 may be coupled to the actuation data register 516 to control the loading of actuation data into actuation data register 516 for a series or set of actuation events.

Mask registers 518 are similar to mask registers 418 described above except that each of mask registers 518 is specifically illustrated as having storage elements or bits 554a-554l which correspond to bits 552a-552l and fluid actuators 512a-512l. Mask registers 518 store sets of mask data for a set of actuation events. The number of mask registers 518 may be equal to the largest number of actuation events in a set of actuation events and may be equal to the largest number of fluid actuators that may be identified for a primitive. Mask registers 518 may be loaded by mask register loading logic 456 each time that a new collection of mask data sets identifying a differently sized primitive to be used. It should be appreciated that mask registers 518 may have more or less storage elements or bits depending upon the number of fluid actuators 512 in array 514.

In one implementation, each mask register 518 stores a single pattern of mask data, wherein the single pattern is shifted in each mask register of the set relative to the same pattern of mask data in the other mask registers 518. As a result, cycling through all of the mask registers 518 of set 550 during a set of actuation events resulting each fluid actuator of each primitive and each actuator of the array being enabled at some time during the set of actuation events. In other implementations, some mask registers 518 may store altered patterns of mask data that are different from the patterns of mask data in the other mask registers 518 40 set of actuation events.

Die input 530 comprises a connection by which instructions for fluid displacement may be received by die 510. In one input, die input 530 comprises an electrical contact pad. In other implementations, die input 530 may comprise other electrical signal receiving structures.

Actuation data load logic 532 comprises logic circuitry such as processing hardware and/or software, coupled to actuation data register 516 to load actuation data register 516 with actuation data received by die input 530. Mask data set(s) registers 534 comprises a memory data register coupled to die input 530 to temporarily store a selection of mask data sets for at least one set of actuation events. In one implementation, a selection of mask data sets and the actuation data may be transmitted in a single packet or in the header of a single packet, wherein die 510 additionally comprises a parser or other logic to distinguish and separate the actuation data from the input pertaining to the selected set of mask data. In one implementation, mask data sets register 534 stores an identification of a set of mask registers to be utilized for a set of actuation events. In one implementation, register 534 may additionally store and order in which masks are to be sequenced. In yet another implementation, registers 534 may store an identifier which selects from a set of sequences to use for sequencing the set of mask registers. For example, in some implementations, the same set of mask data in a mask register may be selected or sequenced multiple times in a set of actuation events very drop weight.

Mask register loading logic 456 is described above. Mask register loading logic loads the mask registers 518 with sets of mask data for being selected and sequenced through during a set of actuation events. Loading of the set 550 of mask registers 518 may take place during periods in which die 510 is inactive. Mask registers loading logic 456 may load less than all of the available registers 518 of set 550 depending upon the number of actuation events in the set of actuation events which is dependent upon the size of the primitive. For example, set 550 may comprise eight registers, facilitating up to eight actuation events in a set of actuation events which correspond to a primitive size of eight fluid actuators. In instances where a set of actuation events is to have four fluid actuators per primitive (as indicated by the input stored in register 534), mask registers loading logic 456 may populate four of the eight available registers for the set of actuation events.

Sequencing logic 340 is coupled to mask registers 518. Sequencing logic 340 operates in a fashion similar to that of sequencing logic 340 of die 410. Sequencing logic 340 comprises logic circuitry that selects and sequences different sets of mask data for individual actuation events of a set or series of actuation events. Sequencing logic 340 connects a selected one of the mask registers 518 to actuation logic 20 for each actuation event of the set of actuation events. FIG. 7 illustrates, in broken lines, an enlarged view of one of mask registers 518 functionally connected to actuation logic 20, illustrating the correspondence between the bits 554 of the selected mask registers 5182 bits 552 of actuation data register 516 and to the individual fluid actuators 512 of array 514. It should be understood that sequencing logic 340 connects one of mask registers 518 to actuation logic 20 and does not load a secondary register with the set of mask data in the selected mask register 518. After each actuation event, sequencing logic 340 selects another mask register 518 for the next actuation event of the set of actuation events. As described above, in one implementation, the sets of mask data in mask registers 518 are selected and sequenced by sequencing logic 340 such that each fluid actuator of each primitive or each fluid actuator of the array is enabled at some time during the set of actuation events.

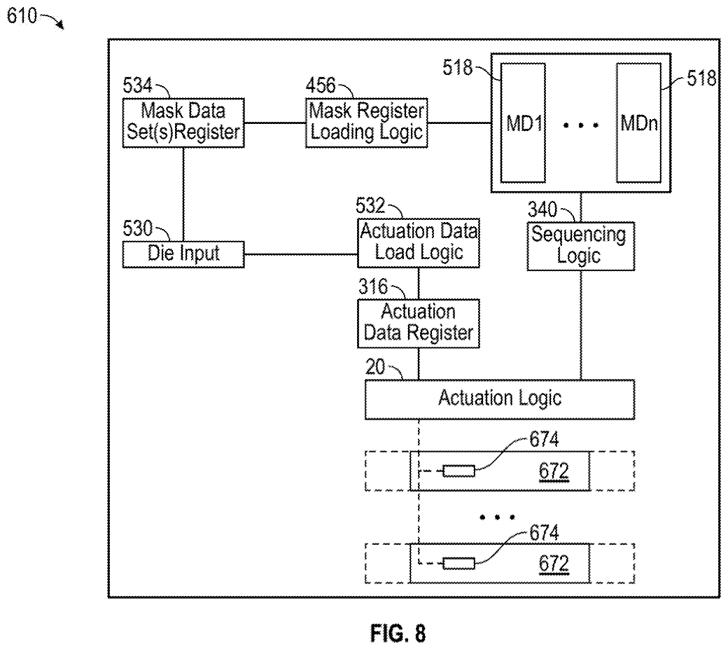

FIG. 8 is a block diagram illustrating some components of an example fluidic die 610. Fluidic die 610 is similar to fluidic die 510 except that fluidic die 610 is specifically illustrated as comprising a plurality of microfluidic channels 672, which may be referred to as an array of microfluidic channels. In the example illustrated, fluid actuators, in the form of fluid pumps 674 are disposed in each microfluidic channel 672. Those remaining components of fluidic die 610 which correspond to components of fluidic die 510 are numbered similarly.

Fluidic die 610 may operate in a fashion similar to that described above with respect to the operation of fluidic die 510. Mask registers loading logic 456 either loads registers 518 of set 550 with sets of mask data for use during a set of actuation events or connects one of sets 552 of mask registers 518 storing preloaded sets of mask data for use during a set of actuation events. Sequencing logic 340 selects one of the mask registers 518 for each actuation event of the set of actuation events and sequences through the different mask registers 518 and there stored different sets of mask data during the set of actuation events.

Actuation logic 20 fires or actuates a subset of the fluid pumps 674 during an actuation event of a set of actuation events based upon the values in actuation register 516 and selected mask register 518. After an actuation event, sequencer logic 340 selects a different mask register of the set 550, 552 and its stored set of mask data. This process is repeated until a set of actuation events has been completed, wherein each fluid pump of the array has been enabled during the set of actuation events. Thereafter, the next set of actuation events may be carried out with the same set of mask registers 518 and stored sets of mask data or may be carried out with a new set of mask registers 518 storing different sets of mask data.

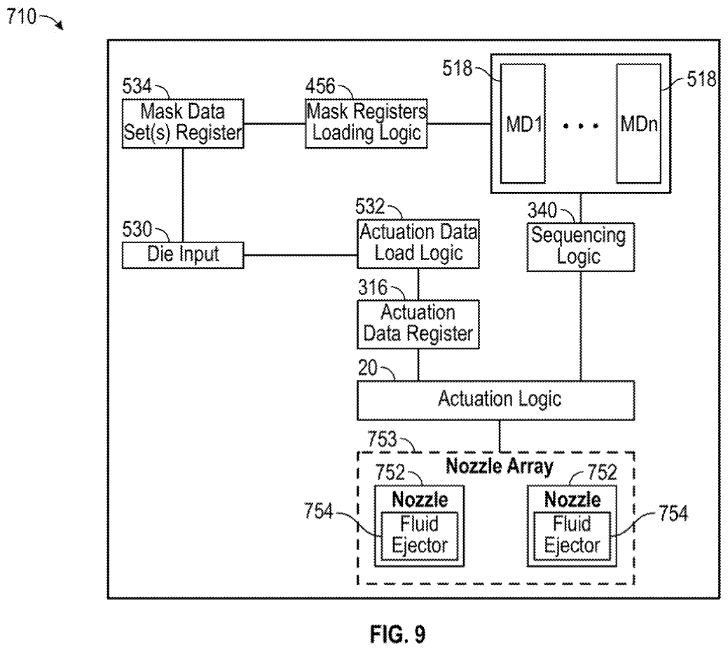

FIG. 9 is a block diagram illustrating some components of an example fluidic die 710. Fluidic die 710 is similar to fluidic die 510 except that fluidic die 710 is specifically illustrated as comprising a plurality of nozzles 752, which may be referred to as an array 753 of nozzles 752. In the example illustrated, fluid actuators, in the form of fluid ejectors 754 provided for each of the nozzles 752. Those remaining components of fluidic die 710 which correspond to components of fluidic die 510 are numbered similarly.

Fluidic die 710 may operate in a fashion similar to that described above with respect to the operation of fluidic die 510. Mask registers loading logic 456 loads registers 518 with sets of mask data for use during a set of actuation events. Sequencing logic 340 selects and connects one of the mask registers 518 to actuation logic 20 for each actuation event of the set of actuation events and sequences through the different mask registers 518 and their stored different sets of mask data during the set of actuation events.

Actuation logic 20 fires or actuates a subset of the fluid ejectors 754/nozzles 752 during an actuation event of a set of actuation events based upon the values in actuation register 516 and the selected mask register 518. After an actuation event, sequencer logic 340 selects a different mask register and its stored set of mask data. This process is repeated until a set of actuation events has been completed, wherein each fluid ejector 752 of the array 753 has been enabled during the set of actuation events. Thereafter, the next set of actuation events may be carried out with the same collection of mask data sets within mask registers 518 or after mask register loading logic 456 has loaded a new collection of mask data sets into mask registers 518.

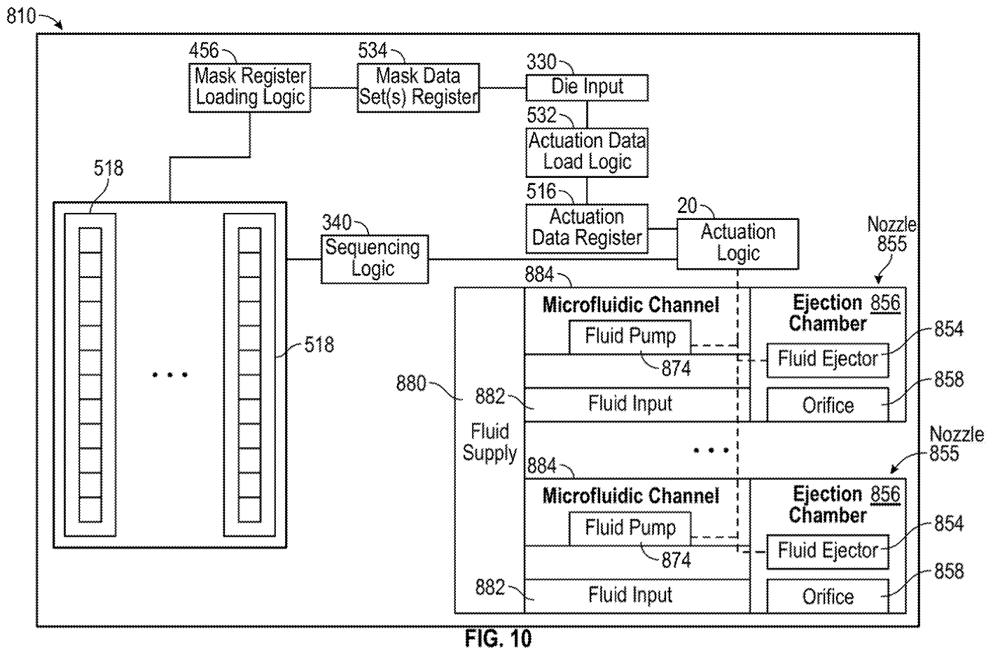

FIG. 10 is a block diagram illustrating some components of an example fluidic die 810. Fluidic die 810 is similar to fluidic die 710 except that fluidic die 810 is illustrated as comprising an array of fluid actuators in the form of fluid ejectors 854 and fluid pumps 874 connected to actuation logic 20. Fluid ejectors 854 and fluid pumps 874 are paired along a fluid supply 880, wherein each of the fluid pumps 874 circulates fluid to and/or from an associated fluid ejector 854.

As further shown by FIG. 10, each fluid ejector 854 is part of a nozzle 855 having an ejection chamber 856 having an orifice 858 and in which the fluid ejector 854 is located. Each ejection chamber 856 is fluidly connected to fluid supply 880 by a fluid input 882 and a microfluidic channel 884. In the example illustrated, each fluid input 882 and microfluidic channel 884 facilitate circulation of fluid into ejection chamber 856, through and across ejection chamber 856 and out of ejection chamber 856 back to fluid supply 880. In the example illustrated, such circulation is facilitated by fluid pump 874 within microfluidic channel 884.

In one implementation, fluid supply 880 comprises an elongate slot supplying fluid to each of the fluid ejectors 854 of the array of dies that are actuated based upon the actuation data contained in actuation data register 516 and the mask data contained in mask register 518. In another implementation, fluid supply 880 may comprise an array of ink feed holes. In one implementation, fluid supply 80 further supplies fluid to fluid ejectors 854 and fluid pumps 874 located on an opposite side of fluid supply 880.

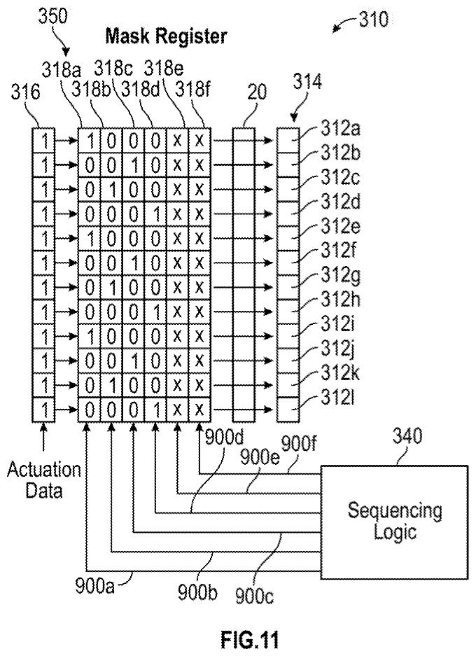

FIGS. 11-13 illustrate one example of fluidic die 510 during a set of actuation events. FIG. 11 illustrates the array 514 of fluid actuators 512, actuation data register 516, mask registers 518a-518f, actuation logic 20 and sequencing logic 340 of fluidic die 510. Each of mask registers 518a-518f may be selected for an actuation event in response to signals transmitted by sequencing logic 340 across address selection lines 900a-900f, respectively. Those remaining components of fluidic die 510 of FIG. 11 are shown and described with respect to FIG. 7.

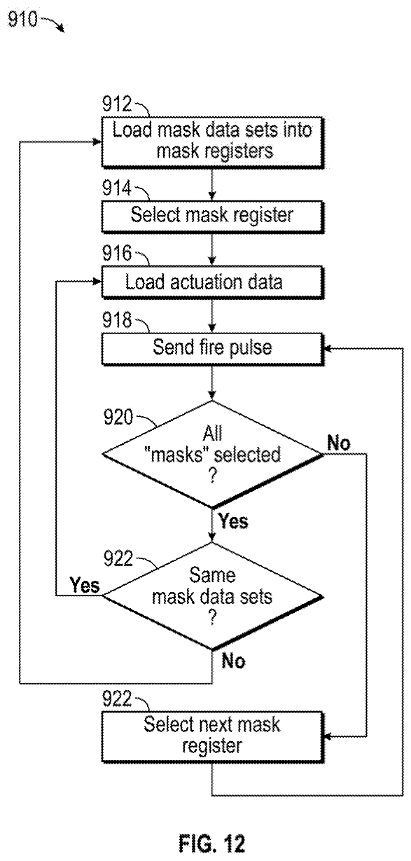

FIG. 12 is a flow diagram illustrating an example method 910 for actuating fluid actuators. Method 910 is described as being carried out with fluidic die 510. It should be appreciative that method 910 may be carried out with any of the above described fluidic dies as well as similar fluidic dies.

As indicated by block 912, mask registers loading logic 456 (shown in FIG. 7) loads the mask data sets into mask registers 518a-518f. In the example illustrated, logic 456 loads or populates four mask registers, registers 518a-518d, to support a set of for actuation events for primitives each comprising four fluid actuators 512. The last two mask registers 518e and 518f are not populated or are not used but are available for subsequent sets of actuation events involving a set of more than four actuation events for a primitive of more than four fluid actuators and up to six actuation events and a primitive of up to six fluid actuators. In the example illustrated, each of mask registers 518a-518f is populated with a pattern of 100010001000, wherein the pattern in each of the mask registers is shifted relative to the pattern in the other mask registers. As shown by FIG. 11, the shifting of the pattern is such that each fluid actuator 512 of array 514 has a corresponding bit in one of the registers 518A-518d with a value of 1 and such that the fluid actuator will be enabled at some time during the set of actuation events involving registers 518a-518d. In the example illustrated, the pattern in mask register 518b is shifted by two places with respect to the pattern in mask register 518a. The pattern in mask register 518c is shifted by one places with respect to the pattern in mask registers 518b. The pattern in mask registers 518d is shifted by two places with respect to the pattern in mask register 518c.

As indicated by block 914, sequencing logic 40 selects one of mask registers 518a-518d for the current actuation event, “event 1”. In the example illustrated, sequencing logic 40 transmits an activating signal along address select line 900a to select the set of mask data stored in registers 518a. Such signals cause logic associated with registers 518a to output values based upon the values of the bits of mask register 518a.

As indicated by block 916, actuation data load logic 532 (shown in FIG. 7) loads the full column of data or actuation data in actuation data register 516. For purposes of the disclosure, each respective bit 552a-l of the actuation data register 516 is loaded with a bit value of “1” such that every fluid actuator 514 (shown in FIG. 8) corresponding to an unmasked bit of set 42 (corresponding to a bit and mask register 516 having a value of “1”) will be actuated or fired (F) during the respective actuation event of the set of actuation events. As should be appreciated, in other implementations, the actual bits 552a-l of actuation data register 516 that are loaded with a bit value of “1” may be less than all of such bits and may be varied depending upon the nozzles or actuators 512 to be fired during the set of actuation events. For example, there may be instances where a particular fluid actuator 512 may correspond to an unmasked bit in mask 518, but will not be fired because the fluid actuator also has a corresponding bit in register 516 with a value of “0”.

As indicated by block 918, actuation logic 918 transmits a fire pulse to fluid actuators 512 based upon the corresponding values in the selected mask register 518a and the corresponding values in actuation data register 516. Actuation logic 20 electrically actuates those fluid actuators having a corresponding bit in register 518A with a value of “1” and a corresponding bit in register 516 having a value of “1”.

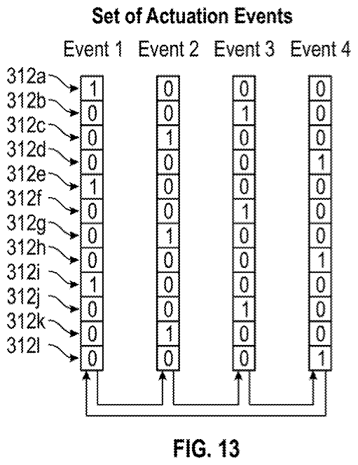

FIG. 13 is a schematic diagram which indicates those fluid actuators 512 that are actuated during each actuation event of the set of four actuation events. As shown by FIG. 11, during the first actuation event, “event 1”, fluid actuators 512a, 512e and 512i are enabled and actuated as their corresponding bits in mask register 518a and in actuation register 516 are both “1”.

As indicated by block 920, sequencing logic 40 determines whether all of masks that have been loaded with sets of mask data, masks 518a-518d have been selected as part of the set of actuation events. As indicated by block 922, in response to mask registers 518 yet to be selected, sequencing logic 40 proceeds by once again selecting the next mask register for the next actuation event, “event 2”. In the example scenario being discussed, sequencing logic 40 would select mask register 518b by transmitting a selection signal on address line 900b. As indicated by block 918, a fire pulse once again be sent by actuation logic 20 resulting in a different subset of actuators 512 being actuated. As shown by FIG. 13, fluid actuators 512c, 512g and 512k are actuated during actuation event 2. Actions set forth in block 918, 920 and 922 are repeated until each of the mask registers 518a-518d have been selected. As shown by FIG. 13, during actuation event 3, fluid actuators 512b, 512f and 512j are enabled and actuated. During actuation event 4, fluid actuators 512d, 512h and 512l are enabled and actuated.

As indicated by block 922, once the set of actuation events has been completed and each of the mask registers 518 populated with sets of mask data has been selected, a determination is made as to whether the next set of actuation events are to use the same mask data sets. In one of limitation, sequencing logic or other logic on die 510 determines from mask data sets registry 34 whether new sets of mask data are to be used for the next set of actuation events. If the same mask data sets are to be used, method 910 proceeds to block 916 where new actuation data is loaded into actuation registry 16 and the actions of blocks 918, 929 22 repeat. If the same mask is sets are not to be used for the next set of actuation events, method 900 proceeds to block 912 where the new math data sets are loaded into mask registers 518. The new sets of mask data may utilize a greater or fewer number of such mask registry one depending upon the size of the primitive to be used during the next set of actuation events.

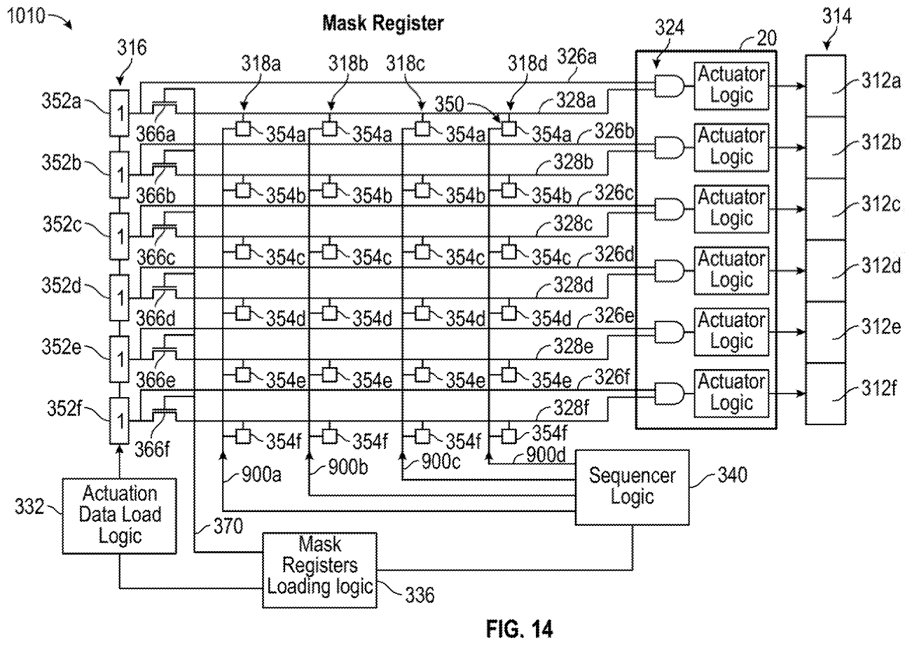

FIG. 14 is a block diagram illustrating components of an example fluidic die 1010, an example implementation of fluidic die 510. Those components of fluidic die 1010 which correspond to components of fluidic die 510 are numbered similarly. Although six fluid actuators 512 and six bits of each of mask registers 518 and actuation data register 516 are illustrated, it should be appreciated that the schema shown in FIG. 14 may be extended to any number of fluid actuators, wherein each of the mask registers 518 and actuation data register 516 would have a corresponding number of bits in the pattern or arrangement illustrated.

As shown by FIG. 14, actuation data register 516 comprises a column of actuation register bits corresponding to the fluid actuator 512 of array 514. The set 550 of mask registers 518 comprise an array of mask register bits arranged in rows and columns, wherein each column of the array comprises mask register bits 554a-554f (collectively referred to as bits 554) which forms one of the mask registers 518a-518f. Each bit 552 of actuation data register 516 is connected to corresponding individual fluid actuator logic 324 of actuation logic 20 by a respective actuation data line 326. Each row of mask register bits 554 is selectively connectable to the respective mask data line 328 which extends along the respective role of mask register bits 554 and which is connected to respective fluid actuator logic 324 of actuation logic 20. The columns of mask register bits 554 forming mask registers 518a-518d are each connected to a respective mask register select line 900a-900d which is connected to sequencer logic 340.

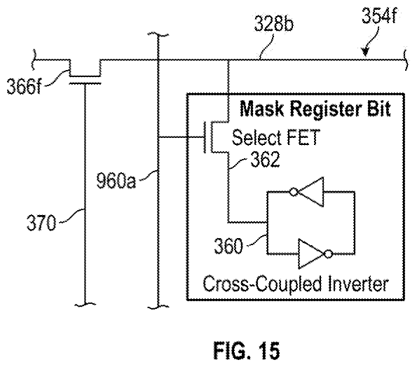

FIG. 15 illustrates one example mask register bit 554 in detail. FIG. 15 illustrates the mask register bit of mask register 518a corresponding to fluid actuator 512f and actuation data register bit 552f. As shown by FIG. 15, each of mask register bits 554 on fluidic die 1010 comprises a memory storage element 360 and a switch 362. In the example illustrated, memory storage element 360 comprises a cross coupled inverter. In other implementations, memory storage element 360 may comprise other memory storage elements or devices. Switch 362 selectively connects memory storage element 360 to a respective mask data line 328 based upon signals received from a respective mask register select line 900.

As further shown by FIG. 14, fluidic die 1010 further comprises switches 366a-366f in the form of thin film transistors that selectively connect respective actuation data register bits 552 to the respective mask data line 328 based upon signals from register write enablement line 370. Register write enablement connected to mask registers loading logic 370.

To load mask registers 518 with sets of mask data, mask registers loading logic 456 output signals to sequencer logic 340 to select one of the mask registers 518a-518f for loading, wherein sequencer logic 340 outputs signals along the mask register select line 900 of the mask registry 518 to be loaded with the set of mask data. This results in switch 362 closing to connect the memory storage element 360 of each mask register bit 554 of the mask register 518 being loaded its respective mask data line 328. Mask register loading logic 456 outputs signals to actuation data load logic 532 so as to load those actuation data bits 552, corresponding to those mask register bits in the mask register 518 which are to be provided with a value of “1”, with an electrical charge corresponding to a “1”. Mask register loading logic 456 further transmits a register write enablement signal along register write enablement line 370, closing each of switches 366 such that the value or charge contained in the respective actuation data register bits 552 are transmitted along the respective mask Adaline 328 and across the respective switch 362 so as to charge or load the respective memory storage element 360 of the respective mask register bit 554.

For example, to load mask register 518a with a set of mask data 010010 correspond to two primitives with each primitive having three fluid actuators, sequencer logic 340 would output mask register selection signals along line 900a, connecting the memory storage element 360 of each mask register bit 554a-554f of mask register 518a to its respective mask data line 328a-328f. Mask registers loading logic 456 would output signals to actuation data load logic 532 causing actuation data load logic 5322 load the corresponding pattern 010010 in actuation data registers 552a-552f, respectively. Mask registers loading logic 456 would further transmit a register write enablement signal or signals along line 372 switches 366a-366f, connecting each of the actuation data registers 552a-552f to its respective mask data line 328a-328f. As a result, the value or charge contained in the respective actuation data register bits 552b and 552e would be transmitted along the respective mask data lines 328b and 328e and across the respective switches 362 so as to charge or load the respective memory storage element 360 of the respective mask register bits 554b and 554e of mask register 518a. Due to the “0” value loaded into actuation data register bits 552a, 552c, 552d and 552f, the mask register bits 554a, 554c, 554d and 554f would also be set at a value of “0”, providing mask register bit 518a with the selected set of mask data 010010.

Once mask registers 518 have been loaded with their respective sets of mask data, the set of actuation events for fluid actuator 512 may be carried out. Actuation data load logic 532 loads the actuation data for the set of actuation events in actuation data register 516. During each actuation event, sequencer logic 340 outputs address selection signals to the selected mask register 518a-518d being used for the particular actuation event of the set. For example, to select mask register 518b, with a lot of 340 would output signals along at a select line 900b, closing the switches 362 of each of the mask register bits 554a-554f of mask register 518b, resulting in their stored values being transmitted to the actuator logic 324 of actuation logic 20 of the respective fluid actuators 512.

The above described loading scheme or architecture utilizes the actuation data register 516 in the sequencer logic 340 for dual purposes: (1) to actuate a subset of the fluid actuators during each actuation event of a set of actuation events and (2) to load the various mask registers 518 with sets of mask data. As a result, die complexity and cost may be reduced. In other implementations, any of the fluidic dies described herein may utilize the loading scheme of FIG. 14 or may utilize other circuitry and loading schemes.

Although the present disclosure has been described with reference to example implementations, workers skilled in the art will recognize that changes may be made in form and detail without departing from the spirit and scope of the claimed subject matter. For example, although different example implementations may have been described as including one or more features providing one or more benefits, it is contemplated that the described features may be interchanged with one another or alternatively be combined with one another in the described example implementations or in other alternative implementations. Because the technology of the present disclosure is relatively complex, not all changes in the technology are foreseeable. The present disclosure described with reference to the example implementations and set forth in the following claims is manifestly intended to be as broad as possible. For example, unless specifically otherwise noted, the claims reciting a single particular element also encompass a plurality of such particular elements. The terms “first”, “second”, “third” and so on in the claims merely distinguish different elements and, unless otherwise stated, are not to be specifically associated with a particular order or particular numbering of elements in the disclosure.

What is claimed is:

1. A fluidic die comprising:
an array of fluid actuators;
an actuation data register to store actuation data that indicates each fluid actuator to actuate for a set of actuation events;
at least one storage device to store sets of mask data, each set of e mask data indicating a set of fluid actuators of the array enabled for actuation for a respective actuation event of the set of actuation events;
sequencing logic coupled to the at least one storage device to select one set of mask data of the set of mask data for each actuation event of the set of actuation events;
actuation logic coupled to the actuation data register, the at least one storage device, and the respective fluid actuators, the actuation logic to electrically actuate a subset of the fluid actuators based at least in part on the actuation data register and the selected set of mask data for the respective actuation event.

2. The fluidic die of claim 1, further comprising:
an array of nozzles, wherein each respective nozzle of the array comprises a respective fluid actuator of the array of fluid actuators as a respective fluid ejector, and each respective fluid ejector is to actuate to thereby eject a fluid drop via the respective nozzle of the array of nozzles.

3. The fluidic die of claim 1, further comprising:
an array of microfluidic channels, wherein each respective microfluidic channel of the array comprises a respective fluid actuator of the array of fluid actuators disposed therein as a respective fluid pump, and each respective fluid pump is to actuate to thereby generate fluid displacement in the respective a microfluidic channel.

4. The fluidic die of claim 1, further comprising:
an array of nozzles, wherein each respective nozzle of the array comprises a first respective fluid actuator of the array of fluid actuators as a respective fluid ejector, and each respective fluid ejector is to actuate to thereby eject a fluid drop via the respective nozzle of the array of nozzles; and
an array of microfluidic channels, wherein each respective microfluidic channel of the array comprises a second respective fluid actuator of the array of a fluid actuators disposed therein as a respective fluid pump, each respective a microfluidic channel is fluidly connected to at least one respective nozzle, and each respective fluid pump is to actuate to thereby generate fluid displacement in the respective microfluidic channel and connected at least one respective nozzle.

5. The fluidic die of claim 1, wherein the at least one storage device comprises a set of mask registers, each of the mask registers of the set to store mask data having a single pattern for the fluid actuators of the array and wherein the single pattern of each mask register of the set is shifted relative to the single pattern of the mask data stored in other mask registers of the set.

6. The fluidic die of claim 1 further comprising a set of mask registers, wherein the loading logic to load a first pattern of mask data into each mask register of the set, the first pattern of mask data being shifted in each mask register of the set relative to the first pattern of mask data in other mask registers of the set, the first pattern of mask data corresponding to a first primitive size and wherein the loading logic is to load a second pattern of mask data into each of the mask registers of the set, the second pattern of mask data corresponding to a a second primitive size that is different than the first primitive size.

7. The fluidic die of claim 6, wherein the loading logic is to begin loading the set of mask registers with a second pattern of mask data prior to completion of sequencing through all of the mask registers of the set of mask registers storing a first pattern of mask data.

8. The fluidic die of claim 1 further comprising an active mask register, wherein the sequencing logic is to load the active mask register with the selected set of mask data after each actuation event.

9. The fluidic die of claim 1 further comprising a set of mask registers, each of the mask registers being actuatable between an active state in which the set of mask data in the mask register is being used by the actuation logic and an inactive state in which the mask register is being loaded with a set of mask data, wherein different mask registers of the set of mask registers are concurrently in the active state and the inactive state.

10. The fluidic die of claim 1, wherein the actuation data register comprises:
a respective bit for each respective fluid actuator,
wherein the at least one storage device comprises a set of mask registers, each mask register of the set comprising a respective bit for each respective fluid actuator, and
wherein the actuation logic to electrically actuate the subset of respective a fluid actuators comprises the actuation logic to electrically actuate the respective fluid actuators based at least in part on the respective bit of the actuation data register and the respective bit of the mask register.

11. The fluidic die of claim 1, wherein the at least one storage device comprises a first set of mask registers, the fluidic die further comprising:
a second set of mask registers, each mask register of the second set to store mask data that indicates a set of fluid actuators of the array enabled for actuation for a respective actuation event of the set of actuation events; and
a selection logic to select one of the first set of mask registers and the second set of mask registers for use with the set of actuation events.

12. The fluidic die of claim 1, wherein the at least one storage device comprises a set of mask registers, wherein the actuation data register comprises a column of actuation register bits and wherein the set of mask registers comprise an array of mask register bits arranged in rows and columns, wherein each column of the array forms one of the mask registers, the fluidic die further a comprising:
actuation data lines, each actuation data line connecting an actuation a register bit to respective fluid actuator logic of a respective fluid actuator;
mask data lines, each mask data line connected to respective fluid actuator logic of a respective fluid actuator and extending along a respective row of the mask register bits;
a register write enablement line connected to write switches to selectively connect the actuation register bits to the mask data lines; and
mask register select lines connected to the sequencer logic, each mask register select line connected to switches of mask register bits of a respective mask register to selectively connect the mask register bits of the respective mask register to respective mask data lines.

13. The fluidic die of claim 1, wherein the at least one storage device comprises a set of mask registers having a number of mask registers equal to a maximum selectable primitive size.

14. A method comprising:
storing sets of mask data on a fluidic die, each set of mask data indicating a set of fluid actuators of an array of fluid actuators enabled for actuation for a respective actuation event of a set of actuation events;
a selecting a set of mask data after each actuation event of the set of actuation events;
a electrically actuating a subset of the fluid actuators based at a least in part on the actuation data register and the sequenced set of mask data for the respective actuation event.

15. The method of claim 14, wherein the sets of mask data are stored in a set of mask registers, the method further comprising beginning loading of the set of mask registers with a second pattern of mask data prior to completion of sequencing through all of the mask registers of the set of mask registers storing a first pattern of mask data different than the second pattern of mask data.
